(19) United States
(12) Patent Application Publication
(10) Pub. No.: US 2004/0233963 A1
(43) Pub. Date: Nov. 25, 2004

(54) Vertical cavity surface emitting laser

(76) Inventors: Stewart Edward Hooper, Oxfordshire (GB); Jonathan Heffernan, Oxford (GB)

Correspondence Address: MARK D. SARALINO (GENERAL), RENNER, OTTO, BOISELLE & SKLAR, LLP, 1621 EUCLID AVENUE, NINETEENTH FLOOR, CLEVELAND, OH, 44115-2191, US

(21) Appl. No.: 10/807,956

(22) Filed: Mar. 24, 2004

(30) Foreign Application Priority Data
Mar. 25, 2003 (GB) 0306778.2

(51) Int. Cl. H01S 3/08; H01S 5/00

(52) U.S. Cl. 372/99; 372/44

(57) ABSTRACT

A semiconductor laser device (15) comprises a substrate (16). A first mirror structure (17), an active region (18) and a second mirror structure (19) are disposed in this order over the substrate (16). The second mirror structure has a first portion (28) having a first width (W₁) and a second portion (29) having a second width (W₂) less than the first width (W₁). The first portion (28) of the second mirror structure (19) is disposed between the second portion (29) of the second mirror structure (19) and the active region (18). An etching stop layer (23) is provided between the first portion (28) of the second mirror structure (19) and the second portion (29) of the second mirror structure (19). A contact (24) is disposed on the surface of the first portion of the second mirror structure, where it is not covered by the second portion of the second mirror structure.

This Nonprovisional application claims priority under 35 U.S.C. §119(a) on Patent Application No. 0306778.2 filed in Great Britain on Mar. 25, 2003, the entire contents of which are hereby incorporated by reference.

### FIELD OF THE INVENTION

The present application relates to a vertical cavity surface emitting laser device, known generally as a “VCSEL”.

### BACKGROUND OF THE INVENTION

FIG. 1 shows the general structure of a VCSEL 1. The device comprises a substrate 2, on one surface of which are provided, in sequence, a first mirror structure 3, an active region 4, and a second mirror structure 5. A buffer layer 6 may be provided between the substrate 2 and the first mirror structure 3, and a cap layer 7 is provided over the second mirror structure 5. A first contact layer 8 is provided on the surface of the substrate opposite to the surface on which the mirror structures and the active layer are provided, and a second contact layer 9 is provided on the cap layer 7.

The active region 4 is a multi-layer structure that includes one or more quantum wells. In FIG. 1, the active region 4 is shown, for illustrative purposes, as comprising two quantum well layers 10. Each quantum well layer is disposed between barrier layers 11.

The mirror structures 3, 5 are again multi-layer structures and each comprise a plurality of layers of a first semiconductor material 13 having a first refractive index alternating with layers of another semiconductor material 14 having a different refractive index. In FIG. 1, each mirror structure is shown as comprising five layers but in practice the number of layers is chosen to provide as great a reflectivity as possible (subject to practical considerations relating to the growth process that may limit the number of layers).

The layers 12 shown in FIG. 1 are cladding layers that space the quantum well layers of the active region 4 from the mirror structures 3, 5.

The substrate 2 and the first multilayer mirror stack 3 are doped so that they have one conductivity type, and the second multilayer mirror stack 5 is doped so as to be the opposite conductivity type. For example, the substrate 2 and the lower mirror stack 3 may be doped n-type and the upper mirror stack may be doped p-type, in which case the contact 8 provided on the lower face of the substrate is the n-type contact and the upper contact 9 disposed on the cap layer 7 is the p-type contact layer.

Where current is caused to flow through the laser device 1 from the lower contact 8 to the upper contact 9, light is generated in the active region 4. The photons generated in the active region 4 are reflected by the mirror stacks 3, 5, and so are returned to the active region 4 thereby producing the well-known lasing effect. The wavelength of the light emitted by the device is determined by the materials used for the quantum well layers 10 and the barrier layers 11 in the active region (which determine the wavelength of light emitted in the active region 4) and by the thicknesses of the layers 13, 14 of the mirror structures 3, 5 (which determine the wavelength at which the reflectivity of the mirror structures is greatest).

VCSEL devices of the general type shown in FIG. 1 are well-known. For example, a VCSEL device with an emission wavelength of around 850 nm may be fabricated using an InGaAs/GaAs multi-layer structure for the active region 4 and using GaAs/GaAlAs multi-layer structures or GaAlAs multi-layer structures for the mirror structures 3, 5.

The VCSEL of FIG. 1 is a “top-emitting” VCSEL, since laser light is emitted from the device through second mirror stack 5, the cap layer 7 and the upper contact 9. “Bottom-emitting” VCSELs are also known, in which light is emitted from the device through the substrate 2. A bottom-emitting VCSEL requires that the substrate is transparent to the emitted light, and this places a significant constraint on the materials that can be used for the substrate. A top-emitting VCSEL avoids this constraint, but will suffer from absorption of light in the cap layer 7.

It is desirable to produce a VCSEL that emits light in the red region of the spectrum, at around 650 nm. A VCSEL that has the general structure shown in FIG. 1 and that has an emission wavelength of approximately 650 nm can in principle be produced. However, the upper mirror structure 5 required for a VCSEL with an emission wavelength of 650 nm typically has a high electrical resistance, and this resistance leads to excessive generation of heat in the laser device.

### SUMMARY OF THE PRIOR ART

WO 00/45483 discloses a semiconductor laser that has a first upper mirror stack that is provided over the active region and that extends over the entire area of the laser. The first upper mirror stack does not have a sufficiently high reflectivity to sustain lasing. A second upper mirror stack is deposited over a central portion of the first upper mirror stack. The combination of the first upper mirror stack and the second upper mirror stack has a sufficiently high reflectivity to sustain lasing. Thus, lasing occurs only in the central portion of the device, where the second upper mirror stack is present, and does not occur in peripheral portions of the device. The laser of WO 00/45483 thus has good optical confinement. Furthermore, the width of the second upper mirror stack is made large enough to support the fundamental lasing mode but is made too small to support other lasing modes, thus giving good control of the lasing mode.

Semiconductor lasers having a two-part upper mirror stack are also disclosed in U.S. Pat. No. 5,577,064, EP-A-0 773 614, U.S. Pat. No. 6,064,683, U.S. Pat. No. 6,185,241 and EP-A-0 803 945. Again, the two-part mirror stack is provided to control optical confinement and/or the lasing mode.

### SUMMARY OF THE INVENTION

The present invention provides a semiconductor laser device comprising: a substrate; a first mirror structure disposed over a first surface of the substrate; an active region disposed over the first mirror structure; a second mirror structure disposed over the active region; and a first contact disposed on a second surface of the substrate; wherein the second mirror structure has a first portion having a first width and a second portion having a second width less than the first width, the first portion being disposed between the second portion and the active region; wherein an etching stop layer is provided over the first portion of the second mirror structure, the second portion of the second mirror structure being disposed over the etching stop layer; and wherein a second contact is disposed over at least part of the surface of the first portion of the second mirror structure not covered by the second portion of the second mirror structure. The present invention provides a laser device in which current is injected into the laser at a point within the second mirror structure, since the contact is provided at an intermediate location, in the thickness direction, of the second mirror structure. Injected current therefore has to travel through only part of the thickness of the second mirror structure, rather than through the entire thickness of the mirror structure. This reduces the resistance of the current path through the second mirror structure, and so reduces the heat generated in the second mirror structure.

The etching stop layer defines the boundary between the first portion of the second mirror structure and the second portion of the second mirror structure. The etching stop layer can be positioned accurately at any desired depth within the second mirror structure during the fabrication process.

The invention is of particular benefit when applied to a top-emitting VCSEL that emits in the wavelength range of approximately 630-680 nm. As explained above, the second mirror structure of a VCSEL emitting in this wavelength range has a high electrical resistance.

The “width” of the second mirror structure as used herein refers to the width in a direction substantially parallel to the face of the substrate on which the mirror structures and the active region are provided. Varying the width of second mirror structure in this way has the effect that only part of the upper surface of the first portion of the second mirror structure is covered by the second portion of the second mirror structure. (The term “upper surface” of the first portion of the second mirror structure as used herein denotes that surface of the first portion of the second mirror structure that is furthest from the substrate and that is substantially parallel to the face of the substrate on which the mirror structures and the active region are provided.) The second contact may then be disposed on a region of the upper surface of the first portion of the second mirror structure which is not covered by the second portion of the second mirror structure.

The second contact may be arranged substantially symmetrically with respect to an axis of the laser device, and the second contact may be annular. This ensures that the current flow through the active region of the laser device is substantially symmetrical.

The second contact may be disposed directly on the etching stop layer.

As noted above, the etching stop layer defines the boundary between the first portion of the second mirror structure and the second portion of the second mirror structure. The etching stop layer can be positioned accurately at any desired depth within the second mirror structure during the fabrication process. Providing the second contact directly on the etching stop layer means that the etching stop layer defines the position of the second contact, and thus allows the second contact to be provided at any desired depth within the second mirror structure.

The position of the second contact is subject to two conflicting requirements—it should be close to the active region, to reduce the depth of the second mirror structure through which the injected current must pass, but it must be sufficiently far from the active region to allow current to diffuse to the centre of the active region. Once an optimum position for the second contact, which balances these conflicting requirements, has been determined, the etching stop layer may be positioned at that point in the structure so that the second contact is correctly positioned. A typical value for the required separation between the second contact and the active region is of the order of 100 nm.

A further advantage of the structure of the present invention is that the etching stop layer and the second contact layer are separated from the active region. In contrast, in existing VCSEL devices in which the contact is disposed on the side of the laser structure, adjacent to the active layer, it is necessary to provide a highly-doped layer adjacent to the active region.

The etching stop layer may be a strained semi-conductor layer. This reduces the optical absorption in the second mirror structure since straining the etching stop layer increases the band-gap of the etching stop layer and so reduces the absorption in the etching stop layer. The etching stop layer is preferably under tensile strain. The etching stop layer is preferably non-absorbing or substantially non-absorbing for light having a wavelength equal to the emission wavelength of the laser.

The etching stop layer may have a thickness of approximately λ/4n where λ is the emission wavelength of the laser and n is the refractive index of the etching stop layer. This minimises the reduction in reflectivity of the second mirror structure caused by providing the etching stop layer.

The laser device may fiber comprise a cap layer disposed over the second mirror structure, and the cap layer may have a thickness of less than 10 nm. Injecting the current into the side of the mirror structure allows the thickness of the cap layer to be reduced, In a conventional device VCSEL, a thick cap layer is required to provide good electrical contact to the p-type mirror structure. In the present invention, however, electrical contact to the p-type mirror structure is not made via the cap layer, so the cap layer is required only to prevent surface oxidation of the mirror and so may be thin. Using a thin cap layer the amount of the emitted laser light that is absorbed in the cap layer is decreased.

The first mirror structure may be doped n-type and the second mirror structure may be doped p-type.

The first and second mirror structures may each comprise an (Al,Ga)As layer structure.

The active region may comprise an (Al,Ga)InP layer structure.

The etching stop layer may be an (Al,Ga)InP layer. It may be a GaInP layer.

The cap layer may be a GaAs cap layer.

The laser may have an emission wavelength of 600 to 700 nm, or of 630 to 680 nm or of 650 to 660 nm. The laser may be a vertical cavity surface emitting laser. As noted above, the mirror structures required for a VCSEL emitting in these wavelength ranges have a high electrical resistivity. The invention is therefore of particular benefit when applied to a VCSEL with an emission wavelength in these ranges.

The invention may, in principle, be applied to either a top-emitting VCSEL or a bottom-emitting VCSEL.

### BRIEF DESCRIPTION OF THE DRAWINGS

Preferred embodiments of the present invention will now be described by way of illustrative example with reference to the accompanying figures in which:

FIG. 1 is a schematic sectional view of a conventional VCSEL;

FIG. 2(a) is a schematic sectional view of a VCSEL according to an embodiment of the present invention;

FIG. 2(b) is a schematic plan view of the VCSEL of FIG. 2(a); and

FIG. 3(a) to 3(c) illustrate the manufacture of a VCSEL of the present invention.

### DETAILED DESCRIPTION OF PREFERRED EMBODIMENTS

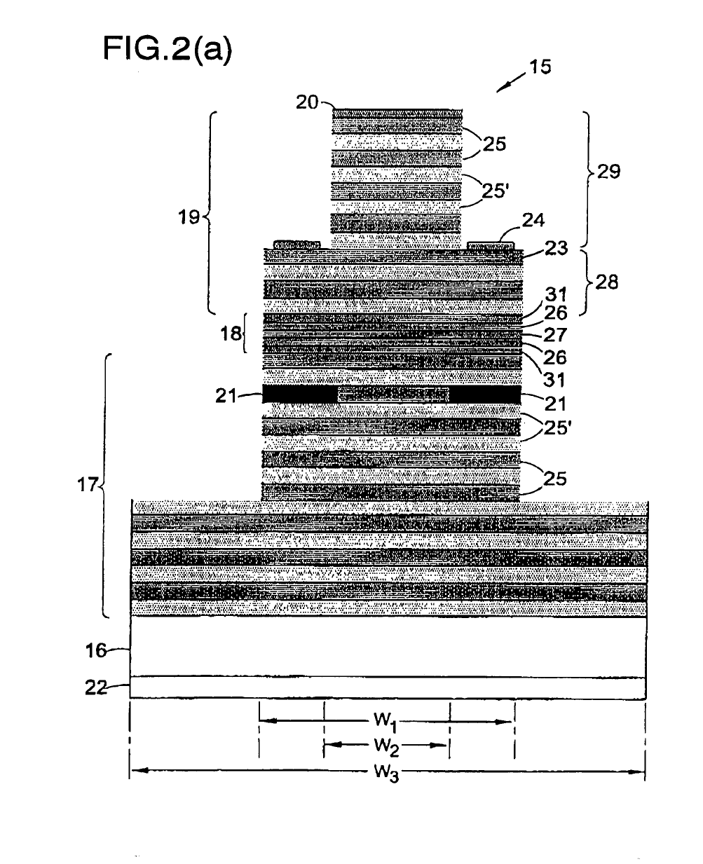

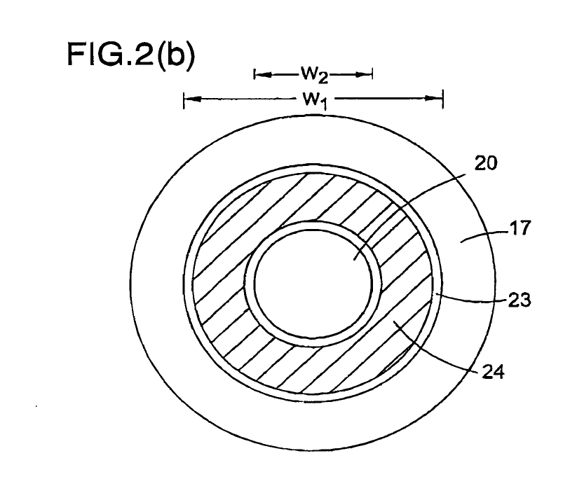

FIG. 2(a) illustrates a VCSEL device according to one embodiment of the present invention. The VCSEL device 15 of FIG. 2(a) comprises a substrate 16, which is a GaAs substrate in this embodiment,

A first mirror structure 17 is disposed on one surface of the substrate. In this embodiment, the first mirror structure is an AlGaAs multilayer structure. It comprises a plurality of layers 25 having a first aluminium mole fraction alternating with layers 25′ having an aluminium mole fraction different from the first aluminium mole fraction. The refractive index of AlGaAs depends on the aluminium mole fraction, so that the refractive index of the second layers 25′ is different from the refractive index of the first layers. The first layers 25 may be GaAs layers, or they may be AlGaAs layers having a an aluminium mole fraction of up to approximately 0.5. The layers 25′ are AlGaAs layers having a higher aluminium mole fraction than the first layers 25, for example an aluminium mole fraction of approximately 0.8 to 0.95. The layers 25, 25′ of the first mirror structure 17 preferably each have a thickness of approximately λ/4nₘ where λ is the intended emission wavelength of the device and nₘ is the refractive index of the layers of the mirror structure. This maximises the reflectivity of the first mirror structure, for a given number of layers in the mirror structure.

The width of the first mirror structure (measured substantially parallel to the surface of the substrate on which the first multilayer mirror structure is grown) in the finished VCSEL of FIG. 2(a) is not constant over the thickness of the first multilayer mirror structure. The layers near the substrate have a width W₃ that is greater than the width of subsequent layers. This “step” in width of the lower multilayer structure gives the layer structure greater stability. In principle, however, the width of the first mirror structure could be constant over the thickness of the first mirror structure.

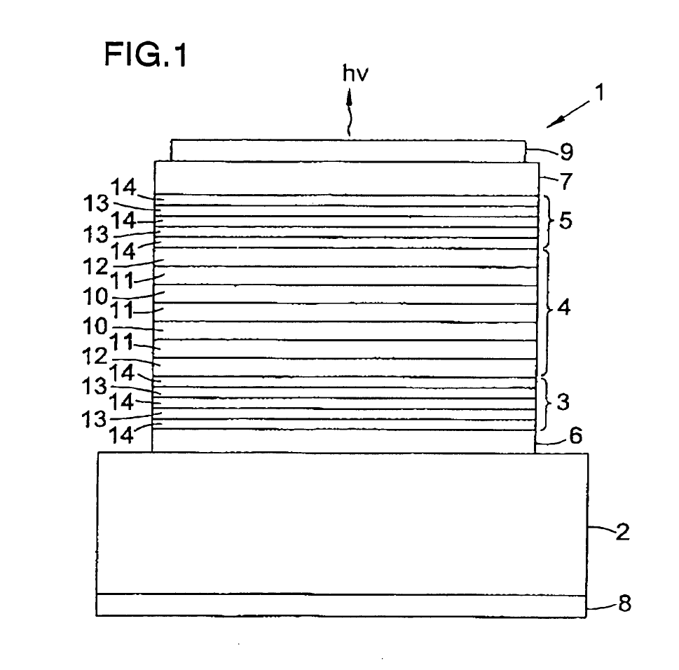

An active region 18 is disposed over the first mirror structure. In this embodiment, the active region comprises an (Al,Ga)InP multi-layer structure comprising two GaInP quantum well layers 26 separated by an AlGaInP barrier layer 27. Cladding layers 31,31 are provided between the active region and the mirror structures (as in the conventional VCSEL of FIG. 1), and the cladding layers may also be AlGaInP layers.

A second mirror structure 19 is disposed over the active region, and this mirror structure again comprises a multi-layer structure in which layers 25 having a low refractive index alternate with layers 25′ of a high refractive index. Each layer of the second mirror structure again preferably has a thickness of approximately λ/4 nₘ. The second mirror structure 19 may again be an AlGaAs multi-layer structure, the layers 25 having a low refractive index may be GaAs layers or AlGaAs layers with an aluminium mole fraction of up to approximately 0.5, and the layers 25′ having a high refractive index may be AlGaAs layers with a mole fraction of approximately 0.8-0.95.

The second mirror structure 19 will be described in more detail below.

A cap layer 20, in this embodiment formed of a layer of GaAs, is disposed over the second mirror structure 19. In a conventional device VCSEL, a thick cap layer is required to provide good electrical contact to the p-type mirror structure. In the present invention, however, electrical contact to the p-type mirror structure is not made via the cap layer, so the cap layer is required only to prevent surface oxidation of the mirror. The cap layer of a VCSEL of the invention may be formed with a thickness of 10 nm or below, and is preferably approximately 5 nm thick. Such a cap layer is much thinner than a cap layer of a conventional VCSEL, and thus absorption in the cap layer of light generated in the active region is reduced. This is a particular advantage when the invention is applied to a top-emitting VCSEL.

A first contact 22 is disposed on the underside of the substrate. The first contact 22 may simply consist of a metallic layer disposed on the surface of the substrate 16 opposite to the surface on which the first mirror structure 17 is disposed.

The substrate 16 and the first mirror structure 17 are doped, to ensure that a conductive path exists from the first contact 22 to the active region 18, The second mirror structure 19 is also doped, to provide a conductive path from the second contact 24, to be described below, to the active region. The second mirror structure is doped to be of the opposite conductivity type to the substrate 16 and the first mirror structure. In the embodiment of FIG. 2(a) the substrate 16 and the first mirror structure 17 are doped n-type, and the second mirror structure is therefore doped p-type. In this embodiment the first contact 22 is an n-type contact and the second contact 24 is a p-type contact.

At least one layer of the first mirror structure 17 is preferably oxidised over part of its widths so as to define an oxide layer having an aperture in the first mirror structure. Oxide regions produced by oxidising a layer of the first mirror structure are denoted schematically by 21 in FIG. 2(a).

The second mirror structure 19 does not have a uniform width over its entire thickness. Instead, as indicated in FIG. 2(a), the second mirror structure comprises a first portion and a second portion, with the two portions having different widths from one another. The first portion 28 of the first mirror structure is disposed over the active region 18, and has a width W₁. The width W₁ of the first portion 28 of the second mirror structure is preferably equal to the width of the active region 18, as indicated in FIG. 2(a). The second portion 29 of the second mirror structure 19 is disposed over the first portion 28 of the second mirror structure, so that the first portion 28 of the second mirror structure is between the active region 18 and the second portion 29 of the second mirror structure 19. The second portion 29 of the second mirror structure 19 has a width W₂ that is less than the width W₁ of the first portion 28 of the second mirror structure. Since the width W₂ of the second portion 29 of the second mirror structure 19 is less than the width W₁ of the first portion 28 of the second mirror structure, a part of the upper surface of the first portion 28 of the second mirror structure 19 is not covered by the second portion 29 of the second mirror structure 19. The second contact 24 is disposed on the upper surface of the first portion 28 of the second mirror structure 19, in a region where it is not covered by the second portion 29 of the second mirror structure 19. As a result, the second contact 24 is disposed at an intermediate location, in the thickness direction, of the second mirror structure 19. The second contact can inject current into an intermediate point, in the thickness direction, of the second mirror structure 19. (The widths W₁ and W₂ are measured substantially parallel to the surface of the substrate on which the VCSEL structure is grown.)

The second contact 24 is thus provided at an intermediate location, in the thickness direction, of the second mirror structure 19. The current injected into the laser structure via the second contact 24 needs to travel through only the first portion of the second mirror structure, and does not need to travel through the entire thickness of the second mirror structure 19. This reduces the resistance of the current path between the second contact 24 and the active region 18.

The present invention is particularly beneficial when applied to a VCSEL that emits in the red wavelength of the spectrum since, as explained above, the mirror structure 19 needed for a laser emitting at this wavelength has a particularly high resistivity. The reduction in the resistance of the current path is, however, a general advantage regardless of the emission wavelength of the laser.

In order to enable the second portion of the second mirror structure 19 to be fabricated reliably, the second mirror structure 19 contains an etching stop layer 23. In this embodiment the etching stop layer 23 is a (AlₓGa₁₋ₓ)_{y}In_{l-y}P layer. The aluminium mole fraction of the etching stop layer may be zero, in which case the etching stop layer is a GaInP layer. Alternatively the aluminium mole fraction may be non-zero. One preferred material for the etching stop layer is Ga_{0.6}In_{0.4}P.

As will be described in more detail below, the second portion 29 of the second mirror structure is defined by an etching process which reduces the width of those layers of the second mirror structure 19 disposed above the etching stop layer 23. The etching stop layer 23 thus defines the boundary between the first portion 28 and the second portion 29 of the second mirror structure, and hence defines the position of the second contact 24. The position of the etching stop layer 23 may be controlled accurately during the fabrication process, so that the etching stop layer 23, and thus the second contact 24, may be provided at any desired point in the second mirror structure 19.

Two conflicting considerations are important in choosing the position for the second contact 24. Firstly, the distance between the second contact 24 and the active region 18 should be kept low, in order to reduce the resistance of the current part. However, it will be seen in FIG. 2 that current is injected into the device near its side edges, and so needs to diffuse inwards into the device to reach the centre of the active region. The distance between the second contact 24 and the active region 18 needs to be sufficiently large to allow the injected current to diffuse to the centre of the laser structure. Typically, the minimum vertical separation required between the active region and the second contact is similar to the thickness of two layers of the mirror structure, which is approximately 100 nm.

The second contact 24 may be positioned directly on the etching stop layer 23. This simplifies the process of etching the second mirror structure to define the second portion 29 of the second mirror structure. The second contact may again be a metallic layer.

FIG. 2(b) is a plan view of the laser structure of FIG. 2(a). It will be seen that the second contact 24 is annular, and extends around the entire circumference of the etching stop layer 23 in this embodiment. This ensures that the current flow path through the laser structure is substantially symmetrical.

The area 24 of the second contact is preferably as large as possible. In FIG. 2(b), therefore, the internal diameter of the annular contact 24 is slightly greater than the diameter W₂ of the second portion 29 of the second mirror structure. The outer diameter of the annular contact 24 is slightly less than the diameter W₁ of the first portion 28 of the second mirror structure.

It should be noted that the invention is not limited to the second contact 24 being annular. In principle, the second contact 24 could have any shape. As noted above, however, it is preferable that the second contact 24 is symmetrical with regard to the longitudinal axis of the laser structure, and so preferably has either rotational symmetry about the longitudinal axis of the laser or reflectional symmetry about a plane that passes through the longitudinal axis of the laser structure.

The etching stop layer 23 is preferably non-absorbing, or at least is not significantly absorbing, for light of the intended emission wavelength of the VCSEL. As a guide, it is preferable for the etching stop layer 23 to absorb less than 25% of light at the intended emission wavelength. One convenient way of reducing the absorption of the etching stop layer 23 for light of the intended emission wavelength of the VCSEL is to make the etching stop layer 23 as a strained layer, preferably as a tensile-strained layer. Making the etching stop layer as a strained layer increases the band-gap of the etching stop layer and reduces the optical absorption in the laser structure above the active region 18. An etching stop layer 23 that is not lattice-matched to the underlying layer provides a strained etching stop layer.

As noted above, a preferred material for the etching stop layer is GaInP. A Ga_{0.52}In_{0.48}P layer grown over an AlGaAs mirror structure will be lattice matched, and hence unstrained. If the Ga:In ratio of the etching stop layer is different from the ratio 0.52:0.48, then the etching stop layer is a strained layer. In particular, the Ga_{0.6}In_{0.4}P etching stop layer mentioned above will be a strained layer when grown over an AlGaAs mirror structure.

The thickness of the etching stop layer 23 is preferably approximately one-quarter of the intended emission wavelength of the laser device. As noted above, the layers of the second mirror structure 19 have a thickness of approximately one-quarter of the emission wavelength of the device, to provide the maximum reflectivity. It is therefore preferable for the etching stop layer 23 has a thickness of approximately one-quarter of the intended emission wavelength, so as to minimises any reduction in reflectivity of the second mirror structure 19 caused by the provision of the etching stop layer. A thickness of one-quarter of the emission wavelength is defined as λ/4n, where λ is the emission wavelength and n is the refractive index of the etching stop layer (at the emission wavelength of the laser). In the case of a laser intended to have an emission wavelength of 650 nm, a GaInP etching stop layer preferably has a thickness of approximately 46 nm.

One method of fabricating the laser device of FIG. 2(a) will now be described. The fabrication of one device will be described for convenience, although in practice a large number of devices will be fabricated on one wafer which is then cleaved into individual devices.

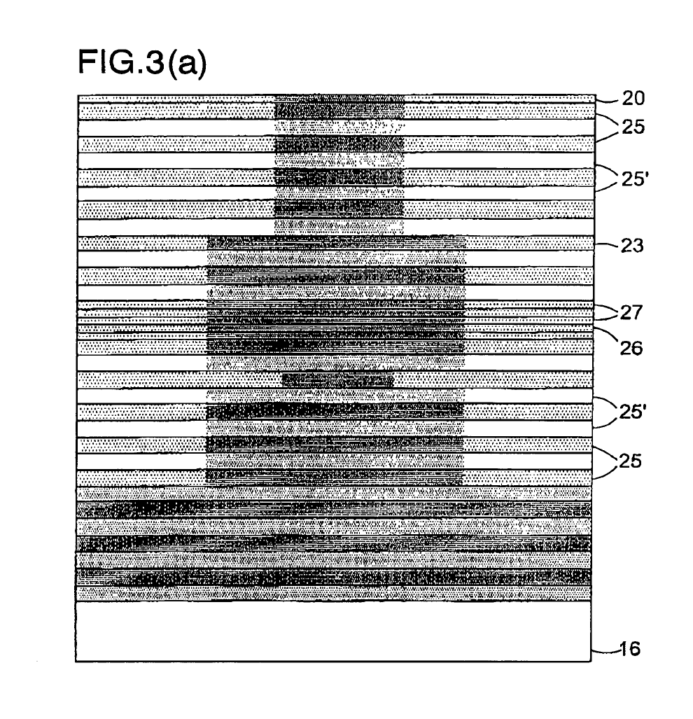

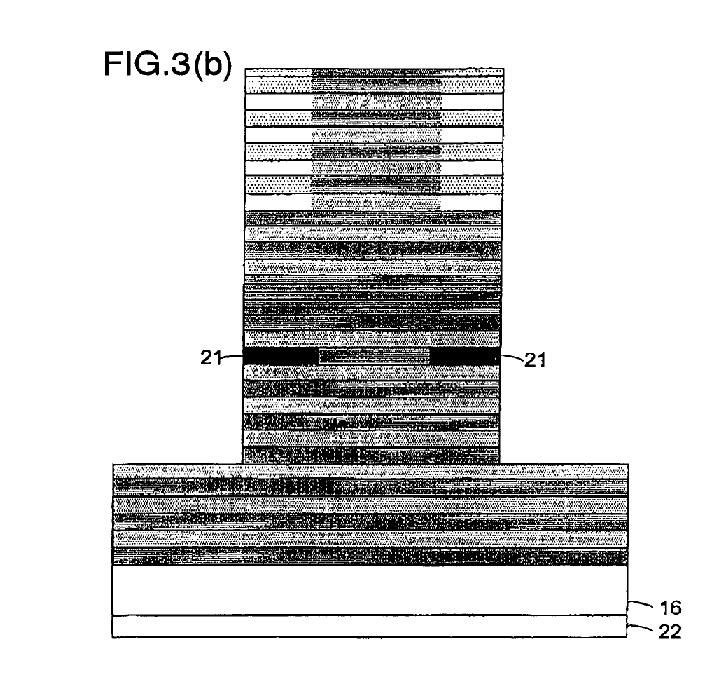

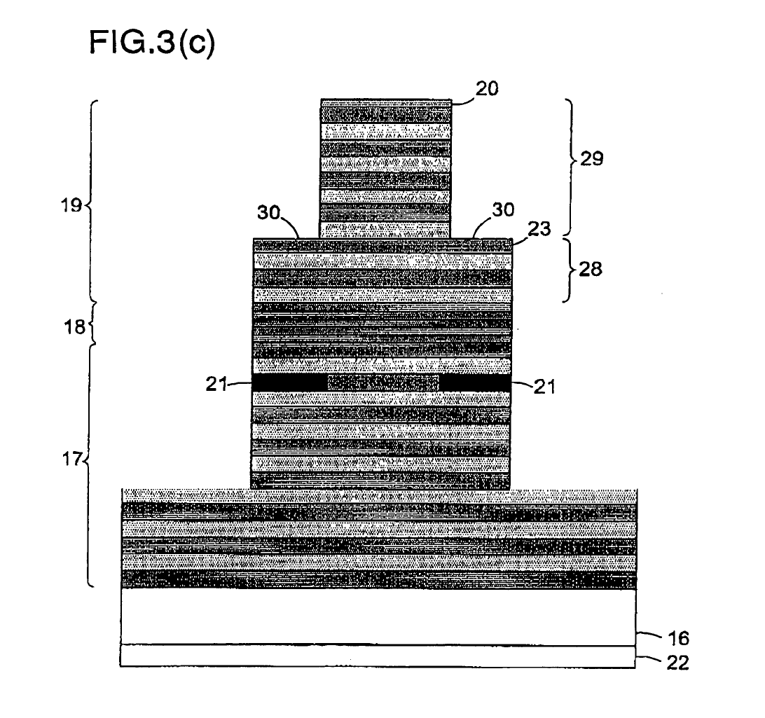

Initially a suitable substrate 16 is selected and cleaned, and the layers 25, 25′ that will form the first mirror structure, the cladding layer 31, the layers 26, 27 that will form the active region, the upper cladding layer 31, and the layers 25, 25′ that will form the second mirror structure 19 are grown over the substrate. Growth of the layers that will form the second mirror structure 19 also includes growth of the etching stop layer 23 at the desired position within the second mirror structure 19. Finally, the cap layer 20 is grown. The layers may be grown using any suitable growth technique such as, for example, molecular beam epitaxy or metal-organic chemical vapour deposition. The results of the epitaxial growth process are shown in FIG. 3(a).

A metallic layer may then be deposited on the underside of the substrate 16, to form the first contact layer 22.

Next, the structure shown in FIG. 3(a) is etched to form a pillar-like mesa structure that extends into the first mirror structure 17. Any suitable etching process may be used, although it should be noted that the etching process used must be able to etch through the etching stop layer 23.

If desired, one or more layers of the lower mirror structure 17 may be oxidised, for example using a wet thermal oxidation process, to produce oxidised regions 21 that define an aperture in the first mirror structure 17.

FIG. 3(b) shows the laser structure after the first etching step, the wet thermal oxidation step, and the step of forming the first contact 22 have been carried out.

The structure of FIG. 3(b) is then subjected to a further etching process, to define the second portion 29 of the second reflective structure. The etchant used in this etching step is one that does not etch, or does not etch significantly, the etching stop layer 23, so that the etching process can be terminated once the mesa structure has been etched down to the etching stop layer 23. A suitable etchant, in the case of a GaInP etching stop layer, is H₂SO₄:H₂O₂:H₂O. FIG. 3(c) shows the result of this second etching process.

The second contact 24 may now be deposited on the exposed surfaces 30 of the etching stop layer 23, to produce the laser structure shown in FIG. 2(a).

Although the invention has been described with reference to specific material systems the invention is not limited to the material systems described above.

In the laser device shown in FIG. 2(a) the active region contains two quantum well layers 26. The invention is not, however, limited to this, and may be applied to a semiconductor laser device in which the active region contains only one quantum well layer or contains more than two quantum well layers.

1. A semiconductor laser device comprising:
a substrate;
a first mirror structure disposed over a first surface of the substrate;
an active region disposed over the first mirror structure;
a second mirror structure disposed over the active region; and
a first contact disposed on a second surface of the substrate;
wherein the second mixer structure has a first portion having a first width and a second portion having a second width less than the first width, the first portion being disposed between the second portion and the active region; wherein an etching stop layer is disposed over the first portion of the second mirror structure, the second portion of the second mirror structure being disposed over the etching stop layer; and wherein a second contact is disposed over at least part of the surface of the first portion of the second mirror structure not covered by the second portion of the second mirror structure.

2. A laser device as claimed in claim 1 wherein the second contact is arranged substantially symmetrically with respect to an axis of the laser device.

3. A laser device as claimed in claim 1 wherein the second contact is annular.

4. A laser device as claimed in claim 1 wherein the second contact is disposed directly on the etching stop layer.

5. A laser device as claimed in claim 1 wherein the etching stop layer is a strained semiconductor layer.

6. A laser device as claimed in claim 1 wherein the etching stop layer is non-absorbing or is substantially non-absorbing for light having a wavelength equal to the intended emission wavelength of the laser device.

7. A laser device as claimed in claim 5 wherein the etching stop layer is non-absorbing or is substantially non-absorbing for light having a wavelength equal to the intended emission wavelength of the laser device.

8. A laser device as claimed in claim 1 wherein the thickness of the etching stop layer is approximately λ/4n, where λ is the emission wavelength of the laser and n is the refractive index of the etching stop layer.

9. A laser device as claimed in claim 5 wherein the thickness of the etching stop layer is approximately λ/4n, where λ is the emission wavelength of the laser and n is the refractive index of the etching stop layer.

10. A laser device as claimed in claim 6 wherein the thickness of the etching stop layer is approximately λ/4n, where λ is the emission wavelength of the laser and n is the refractive index of the etching stop layer.

11. A laser device as claimed in claim 7 wherein the thickness of the etching stop layer is approximately λ/4n, where λ is the emission wavelength of the laser and n is the refractive index of the etching stop layer.

12. A laser device as claimed in claim 1 and further comprising a cap layer disposed over the second mirror structure.

13. A laser device as claimed in claim 12, wherein the cap layer has thickness of less than 10 nm.

14. A laser device as claimed in claim 1 wherein the first mirror structure is doped n-type and the second mirror structure is doped p-type.

15. A laser device as claimed in claim 1 wherein the first and second mirror structures each comprise an (Al,Ga)As layer structure.

16. A laser device as claimed in claim 1 wherein the active region comprises an (Al,Ga)InP layer structure.

17. A laser device as claimed in claim 1, wherein the etching stop layer is an (Al,Ga)InP layer.

18. A laser device as claimed in claim 17 wherein the etching stop layer is a GaInP layer.

19. A laser device as claimed in claim 12, wherein the cap layer is a GaAs cap layer.

20. A laser device as claimed in claim 1 and having an emission wavelength in the range of 600 nm to 700 nm.

21. A laser device as claimed in claim 1 and having an emission wavelength in the range of 630 nm to 680 nm.

22. A laser device as claimed in claim 1 and having an emission wavelength in the range of 650 nm to 660 nm.

23. A laser device as claimed in claim 1 wherein the laser device is a vertical cavity surface emitting laser device.
